(19) United States
(12) Patent Application Publication
(10) Pub. No.: US 2024/0318299 A1
(43) Pub. Date: Sep. 26, 2024

(54) DEPOSITION SOURCE AND APPARATUS FOR MANUFACTURING DISPLAY APPARATUS

(71) Applicant: Samsung Display Co., Ltd., Yongin-si (KR)

(72) Inventors: Eunseok Song, Yongin-si (KR); Taeho Kim, Yongin-si (KR)

(21) Appl. No.: 18/611,480

(22) Filed: Mar. 20, 2024

(30) Foreign Application Priority Data
Mar. 24, 2023 (KR) 10-2023-0039129
Aug. 17, 2023 (KR) 10-2023-0107854

(51) Int. Cl. C23C 14/04; C23C 14/26; H10K 71/16

(52) U.S. Cl. CPC C23C 14/042; C23C 14/26; H10K 71/166

(57) ABSTRACT

A deposition source and an apparatus for manufacturing a display apparatus are provided. A deposition source includes a housing accommodating a deposition material therein, a nozzle connected to the housing, the nozzle for spraying the deposition material accommodated in the housing, a heating portion adjacent to the housing, the heating portion for heating the deposition material accommodated in the housing, and a Peltier plate covering a surface of the housing in which the nozzle is arranged.

### CROSS-REFERENCE TO RELATED APPLICATION

The present application claims priority to and the benefit of Korean Patent Application Nos. 10-2023-0039129, filed on Mar. 24, 2023, and 10-2023-0107854, filed on Aug. 17, 2023, in the Korean Intellectual Property Office, the entire content of each of which is hereby incorporated by reference.

### BACKGROUND

### 1. Field

One or more embodiments relate to a deposition source and an apparatus for manufacturing a display apparatus, and for example, to a deposition source and an apparatus for manufacturing a display apparatus with improved deposition quality.

### 2. Description of the Related Art

Recently, electronic devices have been widely utilized. Electronic devices have been utilized in one or more suitable ways, for example, as movable electronic devices and/or stationary electronic devices. To support various functions, these electronic devices include a display apparatus capable of providing a user with visual information such as images or videos.

Display apparatuses are devices for visually displaying data, and are formed by depositing one or more suitable layers such as an organic layer, a metal layer, and/or the like. A deposition material may be deposited to form a plurality of layers of a display apparatus. For example, a deposition material may be sprayed from a deposition source and deposited on a substrate through a mask assembly. In this state, heat between the deposition source and the mask assembly may deform the mask assembly and/or a display substrate.

The background technology described above is technical information that the inventor may have possessed for the derivation of the present disclosure or may have acquired in the derivation process of the present disclosure, and it should not be said that it is known technology disclosed to the general public before the filing of the present disclosure.

### SUMMARY

Aspects of one or more embodiments of the present disclosure relate to a deposition source and an apparatus for manufacturing a display apparatus, which may improve deposition quality by absorbing heat between the deposition source and a mask assembly.

However, such an aspect and/or objective is an example, and the objective to be solved by the disclosure is not limited thereto.

Additional aspects will be set forth in part in the description which follows and, in part, will be apparent from the description, or may be learned by practice of the presented embodiments of the disclosure.

According to one or more embodiments of the present disclosure, a deposition source includes a housing accommodating a deposition material therein, a nozzle connected to the housing, the nozzle for spraying the deposition material accommodated in the housing, a heating portion adjacent to the housing, the heating portion for heating the deposition material accommodated in the housing, and a Peltier plate covering a surface of the housing in which the nozzle is arranged.

In one or more embodiments, the Peltier plate may be for absorbing heat outside the deposition source and may be for transferring the heat to the inside of the deposition source.

In one or more embodiments, the deposition source may further include a deposition frame having an inner space in which the housing and the heating portion are accommodated, the deposition frame having an opening at at least a part of one surface of the deposition frame in which the nozzle is arranged, wherein the Peltier plate covers the part of the one surface of the deposition frame, and the nozzle extends through the Peltier plate.

In one or more embodiments, the Peltier plate is a single piece that covers an entire open surface of the deposition frame.

In one or more embodiments, the nozzle may include a plurality of nozzles, and the Peltier plate may include a plurality of Peltier plates and the number of the plurality of Peltier plates corresponds to the number of the plurality of nozzles.

In one or more embodiments, in a plan view, each of the plurality of Peltier plates may be around a respective one of the plurality of nozzles.

In one or more embodiments, the Peltier plate may include a first Peltier plate covering an upper surface of the housing in which the nozzle is arranged and a second Peltier plate around side surfaces of the housing.

In one or more embodiments, the deposition source may further include a cooling portion arranged on one surface of the Peltier plate facing the housing to cool heat from the Peltier plate.

In one or more embodiments, the deposition source may further include a reflector between the housing and the Peltier plate, the reflector being to reflect and/or reduce heat generated from an inner space of the deposition source from being transferred to the outside of the deposition source.

In one or more embodiments, the reflector may include a plurality of reflectors spaced from each other in a direction from the housing to the Peltier plate.

In one or more embodiments, the Peltier plate may include a first plate and a second plate, the first plate and the second plate each including an insulator, and a Peltier element layer between the first plate and the second plate and including a semiconductor.

According to one or more embodiments of the present disclosure, an apparatus for manufacturing a display apparatus includes a mask assembly, and a deposition source for supplying a deposition material toward the mask assembly, wherein the deposition source includes a housing accommodating a deposition material therein, a nozzle connected to the housing, the nozzle for spraying the deposition material accommodated in the housing, a heating portion adjacent to the housing, the heating portion for heating the deposition material accommodated in the housing, and a Peltier plate between the housing and the mask assembly.

In one or more embodiments, the Peltier plate may be for absorbing heat outside the deposition source and for transferring the heat to the inside of the deposition source.

In one or more embodiments, the apparatus may further include a deposition frame having an inner space in which the housing and the heating portion are accommodated, the deposition frame having an opening at at least a part of one surface of the deposition frame in which the nozzle is arranged, wherein the Peltier plate covers the part of the one surface of the deposition frame, and the nozzle extends through the Peltier plate.

In one or more embodiments, the Peltier plate may be a single piece that covers an entire open surface of the deposition frame.

In one or more embodiments, the nozzle may include a plurality of nozzles, and the Peltier plate includes a plurality of Peltier plates and a number of the plurality of Peltier plates corresponds to a number of the plurality of nozzles.

In one or more embodiments, in a plan view, each of the plurality of Peltier plates may be around a respective one of the plurality of nozzles.

In one or more embodiments, the Peltier plate may include, a first Peltier plate covering an upper surface of the housing in which the nozzle is arranged and a second Peltier plate around side surfaces of the housing.

In one or more embodiments, the apparatus may further include a cooling portion arranged on one surface of the Peltier plate facing the housing to cool heat from the Peltier plate.

In one or more embodiments, the apparatus may further include a reflector between the housing and the Peltier plate to reflect and/or reduce heat generated from an inner space of the deposition source from being transferred to the outside of the deposition source.

Other aspects, features, and/or principles of embodiments of the present disclosure in addition to those described above will become more apparent from the following drawings, claims, and detailed description of the disclosure.

### BRIEF DESCRIPTION OF THE DRAWINGS

The above and other aspects, features, and/or principles of certain embodiments of the disclosure will be more apparent from the following description taken in conjunction with the accompanying drawings, in which:

FIG. 1 is a schematic cross-sectional view of an apparatus for manufacturing a display apparatus according to one or more embodiments of the present disclosure;

FIG. 2 is a schematic perspective view of a deposition source according to one or more embodiments of the present disclosure;

FIG. 3 is a schematic cross-sectional view of a deposition source according to one or more embodiments of the present disclosure, which may correspond to a cross-section taken along line III-III′ of FIG. 2;

FIGS. 4 and 5 are each a schematic perspective view of a deposition source according to embodiments of the present disclosure;

FIGS. 6-8 are each a schematic cross-sectional view of a deposition source according to embodiments of the present disclosure;

FIG. 9 is a schematic plan view of a display apparatus manufactured by an apparatus for manufacturing a display apparatus according to one or more embodiments of the present disclosure; and

FIG. 10 is a schematic cross-sectional view of a display apparatus manufactured by an apparatus for manufacturing a display apparatus according to one or more embodiments of the present disclosure, which may correspond to a cross-section of the display apparatus taken along line X-X′ of FIG. 9.

### DETAILED DESCRIPTION

The present disclosure may be modified in many alternate forms, and thus specific embodiments will be illustrated in the drawings and described in more detail. It should be understood, however, that this is not intended to limit the present disclosure to the particular forms disclosed, but rather, is intended to cover all modifications, equivalents, and alternatives falling within the spirit and scope of the present disclosure.

Reference will now be made in more detail to embodiments, examples of which are illustrated in the accompanying drawings, wherein like reference numerals refer to like elements throughout, and duplicative descriptions thereof may not be provided. In this regard, the present embodiments may have different forms and should not be construed as being limited to the descriptions set forth herein. Accordingly, the embodiments are merely described below, by referring to the drawings, to explain aspects of the present description. These embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described.

As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof. Unless otherwise apparent from the disclosure, expressions such as “at least one of,” “a plurality of,” “one of,” and other prepositional phrases, when preceding a list of elements, should be understood as including the disjunctive if written as a conjunctive list and vice versa. For example, the expressions “at least one of a, b, or c,” “at least one of a, b, and/or c,” “one selected from the group consisting of a, b, and c,” “at least one selected from a, b, and c,” “at least one from among a, b, and c,” “one from among a, b, and c”, “at least one of a to c” indicates only a, only b, only c, both a and b, both a and c, both b and c, all of a, b, and c, or variations thereof.

Various modifications may be applied to the present embodiments, and particular embodiments will be illustrated in the drawings and described in the detailed description section. The effect and features of the present embodiments, and a method to achieve the same, will be clearer referring to the detailed descriptions below in conjunction with the drawings. However, the present embodiments may be implemented in one or more suitable forms, and are not limited to the embodiments presented below.

Hereinafter, embodiments will be described in more detail with reference to the accompanying drawings, and in the description with reference to the drawings, the same or corresponding constituents may be indicated by the same reference numerals and redundant descriptions thereof may not be provided.

In the following embodiment, it will be understood that although the terms “first,” “second,” etc. may be utilized herein to describe one or more suitable elements, these elements should not be limited by these terms. These elements are only utilized to distinguish one element from another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be further understood that the terms “comprises,” “comprising,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

It will be understood that when an element, such as a layer, film, region, or plate, is referred to as being “on” or “connected to” another element, it can be directly on or connected to the other element or layer, or one or more intervening elements or layers may be present. In addition, it will also be understood that when an element or layer is referred to as being “between” two elements or layers, it can be the only element or layer between the two elements or layers, or one or more intervening elements or layers may also be present.

Sizes of elements in the drawings may be exaggerated for convenience of explanation. For example, because sizes and thicknesses of elements in the drawings may be arbitrarily illustrated (e.g., exaggerated for clarity) for convenience of explanation, the following embodiments are not limited thereto.

Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

In the following embodiment, the X-axis, the V-axis, and the Z-axis are not limited to three axes of the rectangular coordinate system, and may be interpreted in a broader sense. For example, the X-axis, the Y-axis, and the Z-axis may be perpendicular to one another, or may represent different directions that are not perpendicular to one another.

When a certain embodiment may be implemented differently, a specific process order may be performed differently from the described order. For example, two consecutively described processes may be performed substantially at the same time or performed in an order opposite to the described order.

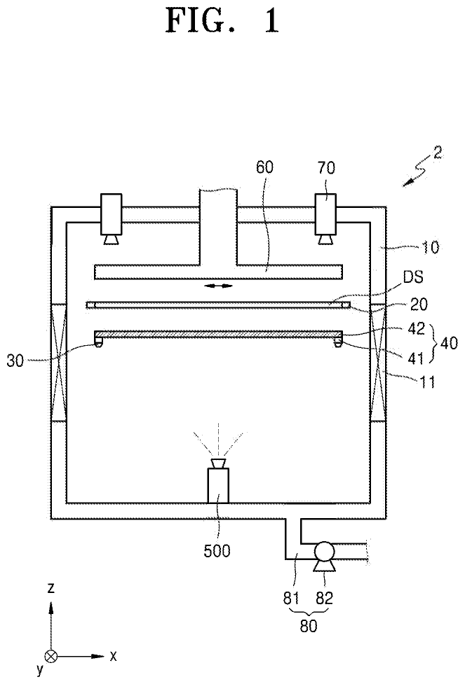

FIG. 1 is a cross-sectional view of an apparatus 2 for manufacturing a display apparatus according to one or more embodiments of the present disclosure.

The apparatus 2 for manufacturing a display apparatus may include a chamber 10, a first support 20, a second support 30, a mask assembly 40, a deposition source 500, a magnetic force portion 60, a vision portion 70, and a pressure adjustment portion 80.

The chamber 10 may have a space inside, and a display substrate DS and the mask assembly 40 may be accommodated therein. In this state, a part of the chamber 10 may be open, and a gate valve 11 may be installed in the open part of the chamber 10. In this case, the open part of the chamber 10 may be open or closed according to the operation of the gate valve 11.

In this state, the display substrate DS may refer to a substrate in the course of manufacturing a display apparatus, for example, a substrate 10 described in more detail below on which at least one of an organic layer, an inorganic layer, and a metal layer is deposited. In one or more embodiments, the display substrate DS may be a substrate, for example, the substrate 100 on which any of an organic layer, an inorganic layer, and a metal layer is not deposited yet.

The first support 20 may support the display substrate DS. In this state, the first support 20 may be in the form of a plate fixed inside the chamber 10. In one or more embodiments, the first support 20, on which the display substrate DS is placed, may be in the form of a shuttle capable of linear motion inside the chamber 10. In one or more embodiments, the first support 20 may include an electrostatic chuck or an adhesive chuck arranged in the chamber 10 to be fixed to the chamber 10 or to be movable inside the chamber 10.

The second support 30 may support the mask assembly 40. In this state, the second support 30 may be arranged inside the chamber 10. The second support 30 may be capable of finely adjusting the position of the mask assembly 40. In this state, the second support 30 may include a separate driving portion or aligning unit to move the mask assembly 40 in different directions.

In one or more embodiments, the second support 30 may be in the form of a shuttle. In such embodiments, the mask assembly 40 may be placed on the second support 30, and the second support 30 may transfer the mask assembly 40. For example, the second support 30 may be moved outside the chamber 10, and when the mask assembly 40 is placed thereon, may enter the inside of the chamber 10 from the outside of the chamber 10.

In one or more embodiments, the first support 20 and the second support 30 may be integrally formed. In such embodiments, the first support 20 and the second support 30 may each include a movable shuttle. In this state, the first support 20 and the second support 30 may include a structure to fix the mask assembly 40 and the display substrate DS while the display substrate DS is placed on the mask assembly 40, and it is possible to allow the display substrate DS and the mask assembly 40 to concurrently (e.g., simultaneously) perform a linear motion.

In the following description, however, for convenience of explanation, a case in which the first support 20 and the second support 30 are formed to be distinguishable from each other (e.g., not integrally formed) and arranged at different positions, and the first support 20 and the second support 30 are arranged inside the chamber 10, is mainly described in more detail.

The deposition source 500 may be arranged to face the mask assembly 40. In this state, the deposition source 500 may accommodate a deposition material, and the deposition material may be vaporized or sublimated by applying heat the deposition material. The deposition source 500 may be fixedly arranged inside the chamber 10 or arranged inside the chamber 10 to be capable of linear motion in a direction.

The mask assembly 40 may be arranged inside the chamber 10. In this state, the mask assembly 40 may include a mask frame 41 and a mask sheet 42. The mask frame 41 may be formed by connecting a plurality of sides, and may include an opening defined by the sides. For example, the opening may be formed by being surrounded by the sides, and the opening may be formed to penetrate the center of the mask frame 41. In one or more embodiments, the mask frame 41 may be a rectangular frame. In this case, the opening may be defined to be a rectangle. The shape of the mask frame 41 is not limited thereto, and may be one or more suitable types (kinds) of polygonal or circular shapes.

The mask sheet 42 may be arranged in the upper portion of the mask frame 41. The opening at the center of the mask frame 41 may be covered by the mask sheet 42. The mask sheet 42 may include an opening area. The opening area may be located at the center of the mask sheet 42, in a plan view. At least one pattern hole may be defined in the opening area. The pattern hole may be a through-hole formed in the mask sheet 42 so that the deposition material may pass through the mask sheet 42. The deposition material having passed through the mask sheet 42 may be deposited on the display substrate DS.

The magnetic force portion 60 may be arranged inside the chamber 10 to face the display substrate DS and/or the mask assembly 40. In this state, the magnetic force portion 60 may apply a force to the mask assembly 40 toward the display substrate DS by applying a magnetic force to the mask assembly 40. In one or more embodiments, the magnetic force portion 60 may not only prevent or reduce sagging of the mask sheet 42 but also make the mask sheet 42 be adjacent to the display substrate DS. Furthermore, the magnetic force portion 60 may maintain a substantially uniform distance between the mask sheet 42 and the display substrate DS.

The vision portion 70 may be arranged in the chamber 10, and may take images (e.g., photograph) the positions of the display substrate DS and the mask assembly 40. In this state, the vision portion 70 may include a camera for photographing the display substrate DS and the mask assembly 40. The vision portion 70 may identify the positions of the display substrate DS and the mask assembly 40 based on the captured image, and check the deformation of the mask assembly 40. Furthermore, the position of the display substrate DS on the first support 20 may be finely adjusted, or the position of the mask assembly 40 on the second support 30 may be finely adjusted, based on the image. In the following description, however, a case in which the positions of the display substrate DS and the mask assembly 40 are aligned with each other by finely adjusting the position of the mask assembly 40 on the second support 30 is mainly described in more detail.

The pressure adjustment portion 80 may be connected to the chamber 10 and may adjust the internal pressure of the chamber 10. For example, the pressure adjustment portion 80 may adjust the internal pressure of the chamber 10 to be the same as or similar to the atmospheric pressure. Furthermore, the pressure adjustment portion 80 may adjust the internal pressure of the chamber 10 to be the same as or similar to a vacuum state.

The pressure adjustment portion 80 may include a connection pipe 81 connected to the chamber 10 and a pump 82 installed on the connection pipe 81. In this state, according to the operation of the pump 82, external air may be introduced into the chamber 10 through the connection pipe 81, or the gas inside the chamber 10 may discharged to the outside through the connection pipe 81.

In a method of manufacturing a display apparatus by utilizing the apparatus 2 for manufacturing a display apparatus as described above, the display substrate DS may be prepared.

The pressure adjustment portion 80 may maintain the inside of the chamber 10 to be the same or similar state as or to the atmospheric pressure, and as the gate valve 11 operates, the open part of the chamber 10 may be open.

Then, the display substrate DS may be loaded into the chamber 10 from the outside. In this state, the display substrate DS may be loaded into the chamber 10 in one or more suitable ways. For example, the display substrate DS may be loaded into the chamber 10 from the outside of the chamber 10 by a robot arm and/or the like arranged outside the chamber 10. In one or more embodiments, when the first support 20 is formed in the form of a shuttle, it is possible that the first support 20 is carried out from the inside of the chamber 10 to the outside of the chamber 10, and then the display substrate DS is placed on the first support 20 by a separate robot arm and/or the like arranged outside the chamber 10, and the first support 20 is loaded into the chamber 10 from the outside of the chamber 10.

The mask assembly 40 may be in a state of being arranged inside the chamber 10 as described above. In one or more embodiments, the mask assembly 40, identically or similarly to the display substrate DS, may be loaded into the chamber 10 from the outside of the chamber 10.

When the display substrate DS is loaded into the chamber 10, the display substrate DS may be placed on the first support 20. In this state, the vision portion 70 may take images (e.g., photograph) the positions of the display substrate DS and the mask assembly 40. In the vision portion 70, the positions of the display substrate DS and the mask assembly 40 may be identified based on the captured image. In this state, the apparatus 2 for manufacturing a display apparatus may include a separate controller and identify the positions of the display substrate DS and the mask assembly 40.

When the identification of the positions of the display substrate DS and the mask assembly 40 is completed, the second support 30 may finely adjust the position of the mask assembly 40.

Then, the deposition source 500 may operate to supply a deposition material to the mask assembly 40, and the deposition material having passed through a plurality of pattern holes of the mask sheet 42 may be deposited on the display substrate DS. In this state, the deposition source 500 may move parallel to the display substrate DS and the mask assembly 40, or the display substrate DS and the mask assembly 40 may move parallel to the deposition source 500. For example, the deposition source 500 may move relative to the display substrate DS and the mask assembly 40. In this state, the pump 82 may maintain the internal pressure of the chamber 10 to be the same as or similar to a vacuum state, by sucking the gas in the chamber 10 and discharging the internal gas to the outside.

As described above, the deposition material supplied from the deposition source 500 may pass through the mask assembly 40 and may be deposited on the display substrate DS, and thus, a plurality of layers, for example, at least one of an organic layer, an inorganic layer, and a metal layer, which are deposited on a display apparatus described in more detail below, may be formed.

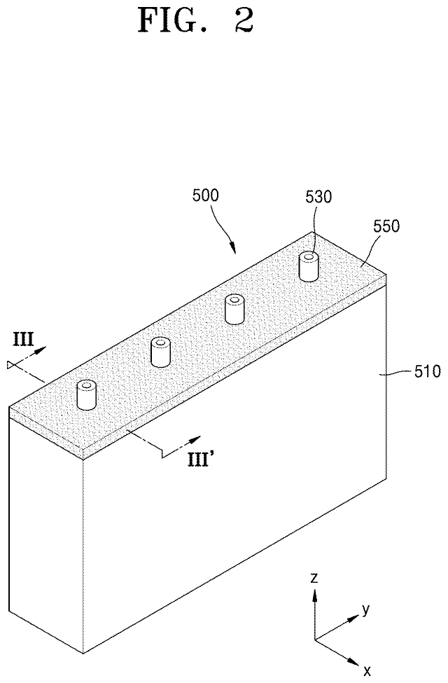

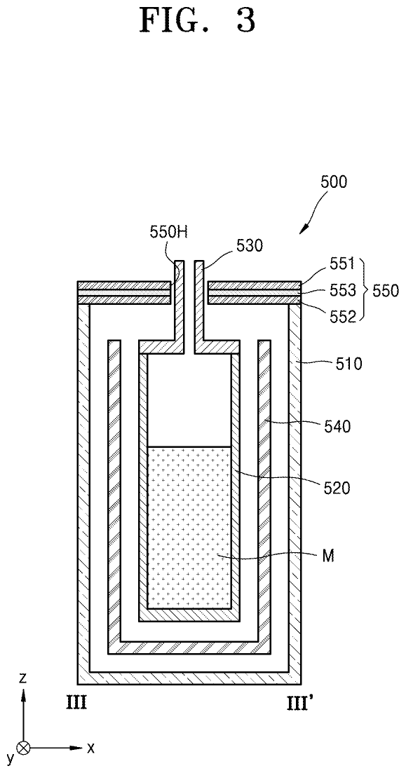

FIG. 2 is a schematic perspective view of the deposition source 500 according to one or more embodiments of the present disclosure. FIG. 3 is a schematic cross-sectional view of the deposition source 500 according to one or more embodiments of the present disclosure, which may correspond to a cross-section taken along line III-III′ of FIG. 2.

Referring to FIGS. 2 and 3, the deposition source 500 may supply a deposition material M to be deposited on the display substrate DS by passing through the mask assembly 40. Although in FIG. 2 one deposition source 500 is illustrated, in one or more embodiments, there may be one or more deposition sources 500. For example, the deposition source 500 may include a first deposition source and a second deposition source, and the first deposition source and the second deposition source may be arranged parallel to each other. In this state, the deposition materials M accommodated in the first deposition source and the second deposition source may be the same or different from each other. In the following description, for convenience of explanation, a case in which only one deposition source 500 is provided is mainly described.

In one or more embodiments, the deposition source 500 may include a deposition frame 510, a housing 520, a nozzle 530, a heating portion 540, and a Peltier plate 550.

The deposition frame 510 may form the appearance of the deposition source 500 and provide an inner space. Other components may be accommodated in the inner space of the deposition frame 510. At least a part of one surface of the deposition frame 510 may be open so that the deposition material M is sprayed to the outside. In one or more embodiments, the deposition frame 510 may have a hexahedral shape, and in this state, at least a part of one surface of the hexahedron may be open. However, this is an example, and the shape of the deposition frame 510 is not limited thereto.

The housing 520 may be arranged in the inner space of the deposition frame 510 to be lead out from the deposition frame 510. The housing 520 may accommodate the deposition material M. In one or more embodiments, the housing 520 may have a hexahedral shape, but the present disclosure is not limited thereto. The nozzle 530 may be connected to one side of the housing 520, and the deposition material M may be sprayed through the nozzle 530.

The heating portion 540 may heat the deposition material M accommodated in the housing 520. For example, the heating portion 540 transmits heat to the housing 520 to vaporize the deposition material M. In one or more embodiments, the heating portion 540 may include a heating member that generates heat. For example, the heating portion 540 may be provided with a heat wire inside. Furthermore, the heating portion 540 may be arranged adjacent to the housing 520 to surround at least a part of the outer surface of the housing 520. For example, the heating portion 540 may be arranged, as illustrated in FIG. 3, to surround the side surface (e.g., the surface facing an x-axis direction) and the lower surface (e.g., the surface facing a −z-axis direction) of the housing 520. Furthermore, the heating portion 540 is accommodated in the deposition frame 510 between the deposition frame 510 and the housing 520. However, the present disclosure is not limited thereto, and in one or more embodiments, the heating portion 540 may be integrally formed into the deposition frame 510.

The Peltier plate 550 may be arranged between the housing 520 and the mask assembly 40. In more detail, the Peltier plate 550 may be arranged to cover at least the open part of the surface of the deposition frame 510. For example, the surface of the deposition frame 510 facing the nozzle 530 may be entirely open. The Peltier plate 550 may be connected to the deposition frame 510, and may be integrally formed to cover the entire surface facing the nozzle 530. For example, when the deposition frame 510 has a hexahedral shape, the Peltier plate 550 may have a rectangular or square shape. In this state, the nozzle 530 may be arranged to penetrate the Peltier plate 550 and may spray the deposition material M in a direction toward the outside of the Peltier plate 550, for example, toward the mask assembly 40. Furthermore, the Peltier plate 550 may have a through-hole 550H through which the nozzle 530 passes.

In one or more embodiments, the Peltier plate 550 may include a first plate 551, a second plate 552, and a Peltier element layer 553. The first plate 551, as an endothermic plate, may be to absorb heat outside the first plate 551, for example, in a side toward the mask assembly 40. The second plate 552, as an exothermic plate, may dissipate heat to the outside of the second plate 552, for example, in a side toward the housing 520. The first plate 551 and the second plate 552 may both be a plate including an insulator (e.g., may each include an insulator). The Peltier element layer 553 may include an n-type or kind semiconductor and a p-type or kind semiconductor that are alternately arranged. Electrodes may be disposed on and below the n-type or kind semiconductor and the p-type or kind semiconductor, respectively. The electrode may be connected to a power so that a current may be applied to the electrode, and as a current is applied to the electrode, heat of the first plate 551 may be absorbed and dissipated to the second plate 552.

According to one or more embodiments, the deposition quality of the apparatus 2 for manufacturing a display apparatus may be improved. In detail, as a distance between the mask assembly 40 and the deposition source 500 decreases, the deposition material M may be easily deposited in a desired or suitable area. However, as the distance between the mask assembly 40 and the deposition source 500 decreases, the heat from the deposition source 500 may thermally expand the mask assembly 40 or the display substrate DS, and thus, inaccurate deposition may be performed. According to one or more embodiments, the Peltier plate 550 may be to absorb heat in a side toward the upper portion of the Peltier plate 550, for example, heat from the deposition source 500 toward the mask assembly 40, in a simple manner. Furthermore, the Peltier plate 550 may operate as a reflector to shield the heat of the deposition material M accommodated in the housing 520 from dissipating to the outside of the deposition source 500. Accordingly, as the heat between the deposition source 500 and the mask assembly 40 is absorbed, the deposition source 500 and the mask assembly 40 may be arranged closer to each other so that the distance between the deposition source 500 and the mask assembly 40 is decreased. Accordingly, the deposition material M may be more efficiently deposited, and a defect due to the thermal expansion of the mask assembly 40 and the display substrate DS, for example, a shadow phenomenon, may be prevented or reduced. Furthermore, the Peltier plate 550 may facilitate the heating of the deposition material M by dissipating heat to a side toward the lower portion of the Peltier plate 550, for example, the housing 520.

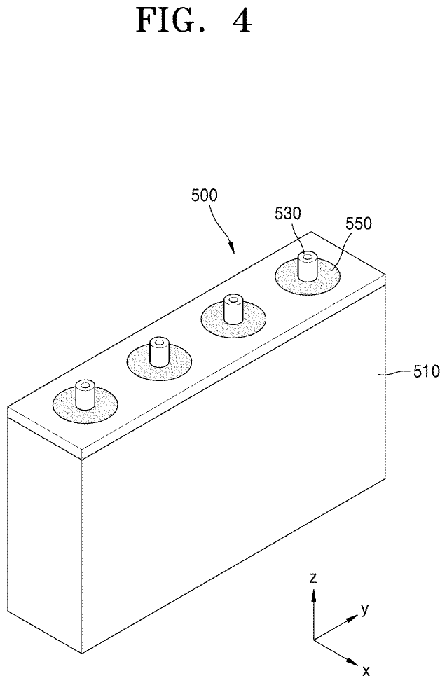

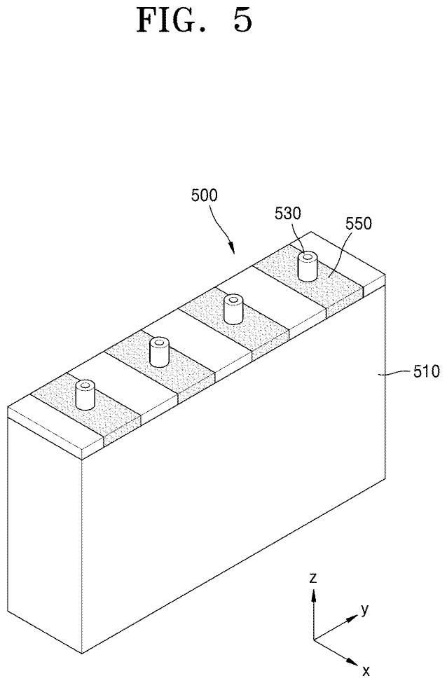

FIGS. 4 and 5 are schematic perspective views of deposition sources according to one or more embodiments. As a deposition source 500 according to the present embodiments are similar to the deposition source 500 described above, in the following description, only differences therebetween are mainly described.

Referring to FIG. 4, in the deposition frame 510, at least a part of one surface, for example, a part of one surface facing the nozzle 530, may be open. For example, a part of one surface facing the nozzle 530 may be open, and the other part thereof may be covered by a plate including the same material as that of the deposition frame 510. In this state, the Peltier plate 550 may be arranged in the open part of one surface.

In one or more embodiments, the nozzle 530 may include a plurality of nozzles. Furthermore, the Peltier plate 550 may include a plurality of Peltier plates, and the number of Peltier plates may correspond to the number of nozzles 530. In this state, the Peltier plates 550 may be respectively arranged to surround the nozzles 530. For example, each of the Peltier plates 550 may have a circular shape around (e.g., surrounding) a respective one of the nozzles 530. The arrangement of the Peltier plate 550 as described above may facilitate efficient absorption of heat around each of the nozzles 530 through which the deposition material M is sprayed. Furthermore, as the Peltier plate 550 includes a plurality of Peltier plates, the operation of each of the Peltier plates 550 may be controlled or selected and the temperature around the deposition source 500 may be effectively controlled or selected.

Referring to FIG. 5, the plate of the deposition frame 510 and the Peltier plate 550 may be alternately arranged. For example, the rectangular plate of the deposition frame 510 and the Peltier plate 550 that is rectangular are alternately arranged to cover the open surface of the deposition frame 510. In this state, the Peltier plate 550 may be arranged to be around (e.g., surround) each of the nozzles 530 as described above. For example, each Peltier plate 550 may have the through-hole 550H so that each of the nozzles 530 may pass therethrough.

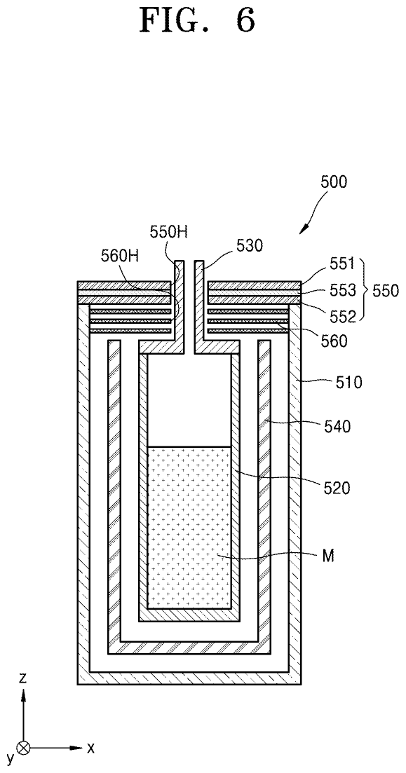

FIGS. 6 to 8 are schematic cross-sectional views of deposition sources according to some embodiments. As a deposition source 500 according to the present embodiments are similar to the deposition source 500 described above, in the following description, only differences therebetween are mainly described.

Referring to FIG. 6, the deposition source 500 may further include a reflector 560. The reflector 560 may prevent or reflect and/or reduce the heat generated from the deposition source 500, for example, the inner space of the deposition frame 510, from being transferred to the mask assembly 40. In one or more embodiments, the reflector 560 may be connected to the deposition frame 510 and arranged between the Peltier plate 550 and the housing 520. Furthermore, the reflector 560 may have a through-hole 560H, through which the nozzle 530 may pass. In one or more embodiments, the reflector 560 may be provided as one reflector, or as illustrated in FIG. 6, may include a plurality of reflectors. The reflectors 560 may be spaced and/or apart (e.g., spaced apart or separated) from each other in a direction from the housing 520 toward the mask assembly 40.

The reflector 560 may prevent or reflect and/or reduce the heat generated from the inner space of the deposition frame 510 from being transferred to the outside of the deposition frame 510, e.g., may prevent or reflect and/or reduce the heat from being transferred to the mask assembly 40, so that expansion of and/or damage to the mask assembly 40 and/or the display substrate DS as a result of the heat may be prevented or reduced. This may, with the Peltier plate 550, increase the thermal efficiency of the deposition source 500 and improve deposition quality.

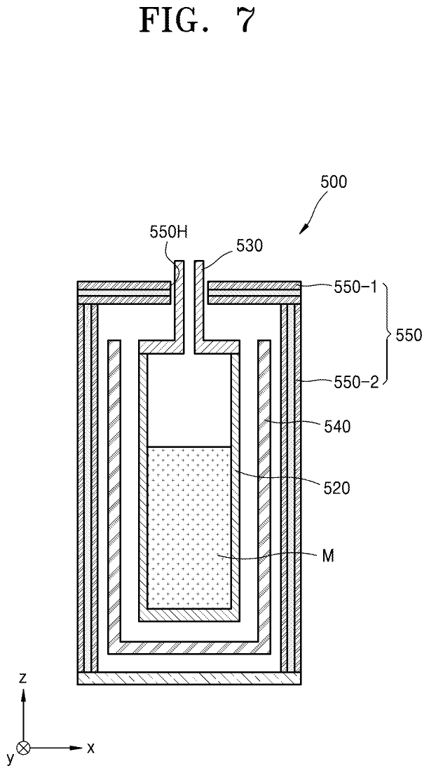

Referring to FIG. 7, in one or more embodiments, the housing 520 may be accommodated in the Peltier plate 550. For example, the Peltier plate 550 may form the appearance (e.g., frame) of the deposition source 500 and provide an inner space. In one or more embodiments, the Peltier plate 550 may include a first Peltier plate 550-1 and a second Peltier plate 550-2. The first Peltier plate 550-1 may be arranged to cover one surface of the housing 520, for example, the surface where the nozzle 530 is arranged. For example, the first Peltier plate 550-1 may cover the upper surface of the housing 520. The nozzle 530 may be arranged to penetrate the first Peltier plate 550-1 as described above.

The second Peltier plate 550-2 may be arranged to surround the side surface of the housing 520. The heating portion 540 may be arranged between the second Peltier plate 550-2 and the housing 520. Furthermore, in one or more embodiments, the Peltier plate 550 may include a third Peltier plate 550-3, and the third Peltier plate 550-3 may be arranged to cover the lower surface of the housing 520. In this case, the Peltier plate 550 may form the appearance of the deposition source 500 and function as a frame. Furthermore, the Peltier plate 550 may be to absorb the heat outside the deposition source 500 and dissipate the heat to the inside of the deposition source 500, and thus, the heat between the deposition source 500 and the mask assembly 40 may be effectively controlled or selected and the deposition source 500 and the mask assembly 40 may be arranged closer to each other so that the distance between the deposition source 500 and the mask assembly 40 is decreased. Furthermore, the heat dissipated to the inside of the deposition source 500 may be utilized to heat the deposition material M.

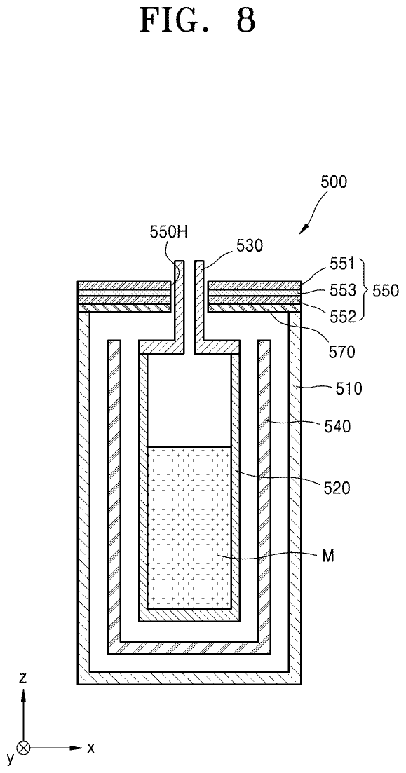

Referring to FIG. 8, the deposition source 500 may further include a cooling portion 570 arranged on one surface of the Peltier plate 550. For example, the cooling portion 570 may be arranged on one surface of the Peltier plate 550 facing the housing 520. For example, the cooling portion 570 may be arranged between the Peltier plate 550 and the housing 520. The cooling portion 570 may remove the heat generated from the second plate 552 of the Peltier plate 550. In one or more embodiments, the cooling portion 570 may be a pipe through which a coolant flows. The coolant may perform heat exchange with the second plate 552 to absorb heat from the second plate 552. However, this is an example, and the configuration of the cooling portion 570 is not limited thereto.

The cooling portion 570 may prevent or reduce the inside of the deposition source 500 from being excessively heated by the heat dissipated from the Peltier plate 550. Furthermore, the cooling portion 570 may increase the operation efficiency of the Peltier plate 550, and effectively control the temperatures inside and outside the deposition source 500.

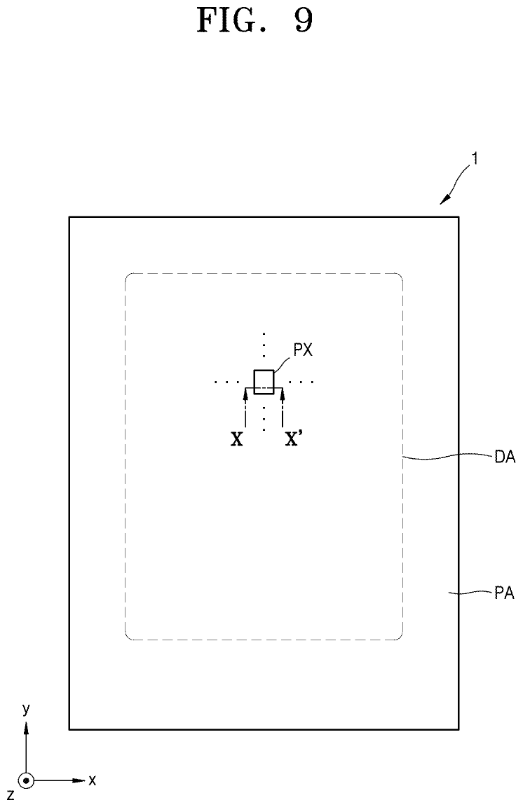

FIG. 9 is a schematic plan view of a display apparatus 1 manufactured by an apparatus for manufacturing a display apparatus according to one or more embodiments of the present disclosure.

Referring to FIG. 9, the display apparatus 1 manufactured according to one or more embodiments may include a display area DA and a peripheral area PA located outside the display area DA. The display apparatus 1 may provide an image through an array of a plurality of pixels PX that are two-dimensionally arranged in the display area DA.

The peripheral area PA, which is an area that does not provide an image, may entirely or partially surround the display area DA. A driver for providing an electrical signal or power to a pixel circuit corresponding to each of the pixels PX, and/or the like, may be arranged in the peripheral area PA. A pad that is an area where electronic components, a printed circuit board, and/or the like are electrically connected may be arranged in the peripheral area PA.

In the following description, although the display apparatus 1 is described as including an organic light-emitting diode (OLED) as a light-emitting element, the present disclosure is not limited thereto. In one or more embodiments, the display apparatus 1 may include a light-emitting display apparatus including an inorganic light-emitting diode, for example, an inorganic light-emitting display apparatus. The inorganic light-emitting diode may include a PN diode including inorganic material semiconductor-based materials. When a voltage is applied to a PN junction diode in a forward direction, holes and electrons are injected, and the energy generated according to a recombination of the holes and electrons is converted into light energy so that light of a certain color may be emitted. The inorganic light-emitting diode described above may have a width of several to hundreds of micrometers, and in one or more embodiments, the inorganic light-emitting diode may be referred to as a micro light-emitting diode (LED). In one or more embodiments, the display apparatus 1 may be a quantum-dot light-emitting display apparatus.

The display apparatus 1 may be utilized as a display screen not only for portable electronic devices, such as mobile phones, smartphones, tablet personal computers (PCs), mobile communication terminals, electronic organizers, electronic books, portable multimedia players (PMPs), navigation devices, ultra-mobile PCs (UMPCs), and/or the like, but also for one or more suitable products, such as televisions, notebook computers, monitors, billboards, internet of things (IoT) devices, and/or the like. Furthermore, the display apparatus 1 according to one or more embodiments may be utilized for wearable devices, such as smart watches, watch phones, glasses type or kind displays, and head mounted displays (HMDs). Furthermore, the display apparatus 1 according to one or more embodiments may be utilized as an instrument panel of a vehicle, a center information display (CID) disposed in the center fascia or dashboard of a vehicle, a room mirror display in lieu of (or in addition to) a side mirror of a vehicle, or a display screen disposed at the rear surface of a front seat as an entertainment device for a rear seat of a vehicle.

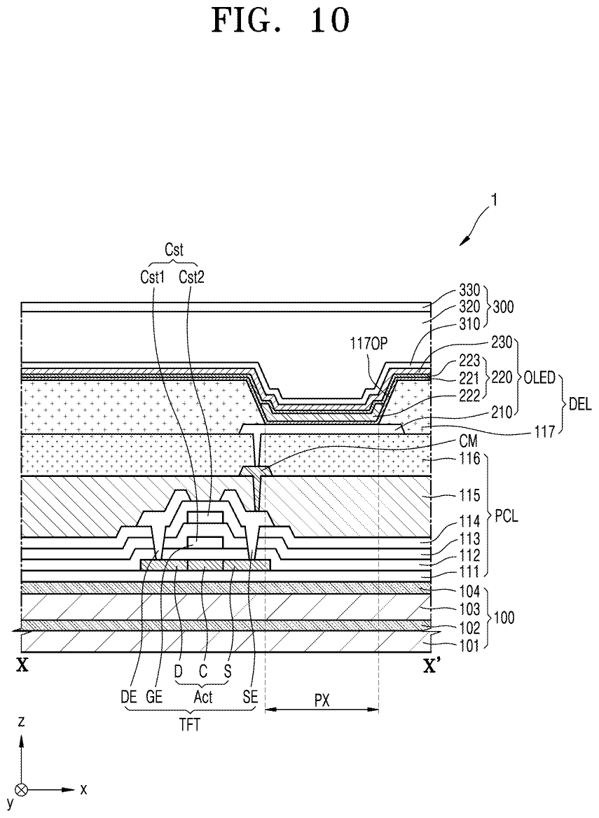

FIG. 10 is a schematic cross-sectional view of the display apparatus 1 manufactured by an apparatus for manufacturing a display apparatus according to one or more embodiments of the present disclosure, which may correspond to a cross-section of the display apparatus taken along line X-X′ of FIG. 9.

Referring to FIG. 10, the display apparatus 1 may include a stack structure of the substrate 100, a pixel circuit layer PCL, a display element layer DEL, and an encapsulation layer 300. The display substrate DS (see, e.g., FIG. 1) described above may be any one or more of the layers of the display apparatus 1 that exists in the process of manufacturing the display apparatus 1, for example, at least any one of the pixel circuit layer PCL, the display element layer DEL, and the encapsulation layer 300 may be stacked thereon.

The substrate 100 may have a multilayer structure of a base layer including polymer resin and an inorganic layer. For example, the substrate 100 may include a base layer including polymer resin and a barrier layer of an inorganic insulating layer. For example, the substrate 100 may include a first base layer 101, a first barrier layer 102, a second base layer 103, and a second barrier layer 104, which are sequentially stacked. The first base layer 101 and the second base layer 103 may include polyimide (PI), polyethersulfone (PES), polyarylate, polyetherimide (PEI), polyethylene naphthalate (PEN), polyethylene terephthalate (PET), polyphenylene sulfide (PPS), polycarbonate (PC), cellulose triacetate (TAC), cellulose acetate propionate (CAP), or/and/or the like. The first barrier layer 102 and the second barrier layer 104 may include an inorganic insulating material, such as a silicon oxide, a silicon oxynitride, and/or a silicon nitride. The substrate 100 may be flexible.

The pixel circuit layer PCL may be disposed on substrate 100. FIG. 10 illustrates that the pixel circuit layer PCL may include a transistor TFT, and a buffer layer 111, a first gate insulating layer 112, a second gate insulating layer 113, an interlayer insulating layer 114, a first planarization insulating layer 115, and a second planarization insulating layer 116, which are disposed below or/and above elements of the transistor TFT.

The buffer layer 111 may reduce or block infiltration of foreign materials, moisture, or external air from under the substrate 100, and provide a planarized surface on the substrate 100. The buffer layer 111 may include an inorganic insulating material, such as a silicon oxide, a silicon oxynitride, or a silicon nitride, and have a single layer or multilayer structure including the material described above.

The transistor TFT on the buffer layer 111 may include a semiconductor layer Act, and the semiconductor layer Act may include polysilicon. In one or more embodiments, the semiconductor layer Act may include amorphous silicon, oxide semiconductor, organic semiconductor, and/or the like. The semiconductor layer Act may include a channel region C, and a drain region D and a source region S respectively arranged on both (e.g., opposite) sides of the channel region C. A gate electrode GE may overlap the channel region C.

The gate electrode GE may include a low resistance metal material. The gate electrode GE may include a conductive material including molybdenum (Mo), aluminum (Al), copper (Cu), titanium (Ti), and/or the like, and may be formed in a multilayer or single layer including the material described above.

The first gate insulating layer 112 between the semiconductor layer Act and the gate electrode GE may include an inorganic insulating material, such as a silicon oxide (SiO₂), a silicon nitride (SiN_{X}), a silicon oxynitride (SiON), an aluminum oxide (Al₂O₃), a titanium oxide (TiO₂), a tantalum oxide (Ta₂O₅), a hafnium oxide (HfO₂), a zinc oxide (ZnO_{X}), and/or the like. ZnO_{X} may include a zinc oxide (ZnO) and/or a zinc peroxide (ZnO₂).

The second gate insulating layer 113 may cover the gate electrode GE. Similar to the first gate insulating layer 112, the second gate insulating layer 113 may include an inorganic insulating material, such as SiO₂, SiN_{X}, SiON, Al₂O₃, TiO₂, Ta₂O₅, HfO₂, ZnO_{X}, and/or the like. ZnO_{X} may include ZnO and/or ZnO₂.

An upper electrode Cst2 of a storage capacitor Cst may be disposed above the second gate insulating layer 113. The upper electrode Cst2 may overlap the gate electrode GE thereunder. The gate electrode GE and the upper electrode Cst2 overlapping each other with the second gate insulating layer 113 therebetween may form the storage capacitor Cst. For example, the gate electrode GE may function as a lower electrode Cst1 of the storage capacitor Cst.

As such, the storage capacitor Cst and the transistor TFT may be formed to overlap each other. In one or more embodiments, the storage capacitor Cst may be formed not to overlap the transistor TFT.

The upper electrode Cst2 may include Al, platinum (Pt), palladium (Pd), silver (Ag), magnesium (Mg), gold (Au), nickel (Ni), neodymium (Nd), iridium (Ir), chromium (Cr), calcium (Ca), Mo, Ti, tungsten (W), and/or Cu, and may be in a single layer or multilayer of one or more of the materials described above.

The interlayer insulating layer 114 may cover the upper electrode Cst2. The interlayer insulating layer 114 may include SiO₂, SiN_{X}, SiON, Al₂O₃, TiO₂, Ta₂O₅, HfO₂, or ZnO_{X}, and/or the like. ZnO_{X} may include ZnO and/or ZnO₂. The interlayer insulating layer 114 may be a single layer or multilayer including one or more of the inorganic insulating materials described above.

A drain electrode DE and a source electrode SE may each be disposed on the interlayer insulating layer 114. The drain electrode DE and the source electrode SE may be respectively connected to the drain region D and the source region S through contact holes formed in insulating layers thereunder. The drain electrode DE and the source electrode SE may each include a highly conductive material. The drain electrode DE and the source electrode SE may each include a conductive material including Mo, Al, Cu, Ti, and/or the like, and may be formed in a multilayer or single layer including one or more of the materials described above. In one or more embodiments, the drain electrode DE and the source electrode SE may have a multilayer structure of Ti/Al/Ti.

The first planarization insulating layer 115 may cover the drain electrode DE and the source electrode SE. The first planarization insulating layer 115 may include an organic insulating material, such as a general purpose polymer including polymethylmethacrylate (PMMA) or polystyrene (PS), a polymer derivative having a phenolic group, an acrylic polymer, an imide-based polymer, an aryl ether-based polymer, an amide-based polymer, a fluorine-based polymer, a p-xylene-based polymer, a vinyl alcohol-based polymer, and/or suitable blends and/or mixtures thereof.

The second planarization insulating layer 116 may be disposed on the first planarization insulating layer 115. The second planarization insulating layer 116 may include the same material as that of the first planarization insulating layer 115, and include an organic insulating material, such as a general purpose polymer including polymethylmethacrylate (PMMA) or polystyrene (PS), a polymer derivative having a phenolic group, an acrylic polymer, an imide-based polymer, an aryl ether-based polymer, an amide-based polymer, a fluorine-based polymer, a p-xylene-based polymer, a vinyl alcohol-based polymer, and/or suitable blends and/or mixtures thereof.

The display element layer DEL may be disposed on the pixel circuit layer PCL having the structure described above. The display element layer DEL may include an organic light-emitting diode OLED as a display element, for example, a light-emitting element, and the organic light-emitting diode OLED may have a stack structure of a pixel electrode 210, an intermediate layer 220, and a common electrode 230. The organic light-emitting diode OLED may be to emit, for example, red, green, or blue light, or red, green, blue, or white light. The organic light-emitting diode OLED may be to emit light through an emission area, and the emission area may be defined as a pixel PX.

The pixel electrode 210 of the organic light-emitting diode OLED may be electrically connected to the transistor TFT through contact holes formed in the second planarization insulating layer 116 and the first planarization insulating layer 115 and a contact metal CM disposed on the first planarization insulating layer 115.

The pixel electrode 210 may include a conductive oxide, such as an indium tin oxide (ITO), an indium zinc oxide (IZO), a zinc oxide (ZnO), an indium oxide (In₂O₃), an indium gallium oxide (IGO), or an aluminum zinc oxide (AZO). In another embodiment, the pixel electrode 210 may include a reflective film including Ag, Mg, Al, Pt, Pd, Au, Ni, Nd, Ir, Cr, or a compound thereof. In one or more embodiments, the pixel electrode 210 may further include a film formed of ITO, IZO, ZnO, or In₂O₃ above/below the reflective film described above.

A pixel defining layer 117 having an opening 117OP exposing the central portion of the pixel electrode 210 is disposed on the pixel electrode 210. The pixel defining layer 117 may include an organic insulating material and/or an inorganic insulating material. The opening 117OP may define the emission area of the light emitted from the organic light-emitting diode OLED. For example, the size/width of the opening 117OP may correspond to the size/width of the emission area. Accordingly, the size and/or width of the pixel PX may depend on the size and/or width of the opening 117OP of the corresponding pixel defining layer 117.

The intermediate layer 220 may include an emission layer 222 formed to correspond to the pixel electrode 210. The emission layer 222 may include a polymer or low molecular weight organic material that emits light of a certain color. In one or more embodiments, the emission layer 222 may include an inorganic light-emitting material or quantum dots.

In one or more embodiments, the intermediate layer 220 may include a first function layer 221 and a second function layer 223 respectively disposed below and above the emission layer 222. The first function layer 221 may include, for example, a hole transport layer (HTL), or an HTL and a hole injection layer (HIL). The second function layer 223, as an element disposed on the emission layer 222, may include an electron transport layer (ETL) and/or an electron injection layer (EIL). The first function layer 221 and/or the second function layer 223 may each be a common layer formed to entirely cover the substrate 100, like the common electrode 230 to be described in more detail below.

The common electrode 230 may be disposed on the pixel electrode 210 and may overlap the pixel electrode 210. The common electrode 230 may include a conductive material having a low work function. For example, the common electrode 230 may include a (semi-)transparent layer including Ag, Mg, Al, Pt, Pd, Au, Ni, Nd, Ir, Cr, lithium (Li), Ca, an alloy thereof, and/or the like. In one or more embodiments, the common electrode 230 may further include a layer including ITO, IZO, ZnO or In₂O₃ on the (semi-)transparent layer including the one or more of the materials described above. The common electrode 230 may be integrally formed to entirely cover the substrate 100.

The encapsulation layer 300 may be disposed on the display element layer DEL to cover the display element layer DEL. The encapsulation layer 300 may include at least one inorganic encapsulation layer and at least one organic encapsulation layer, and in one or more embodiments, FIG. 13 illustrates that the encapsulation layer 300 includes a first inorganic encapsulation layer 310, an organic encapsulation layer 320, and a second inorganic encapsulation layer 330, which are sequentially stacked.

The first inorganic encapsulation layer 310 and the second inorganic encapsulation layer 330 may each include one or more inorganic materials of an aluminum oxide, a titanium oxide, a tantalum oxide, a hafnium oxide, a zinc oxide, a silicon oxide, a silicon nitride, and/or a silicon oxynitride. The organic encapsulation layer 320 may include a polymer-based material. The polymer-based material may include acrylic resin, epoxy-based resin, polyimide, polyethylene, and/or the like. In one or more embodiments, the organic encapsulation layer 320 may include acrylate. The organic encapsulation layer 320 may be formed by curing a monomer or coating a polymer. The organic encapsulation layer 320 may be transparent.

In one or more embodiments, a touch sensor layer may be disposed on the encapsulation layer 300, and an optical function layer may be disposed on touch sensor layer. The touch sensor layer may obtain an external input, for example, coordinates information according to a touch event. The optical function layer may reduce reflectivity of light (external light) incident on the display apparatus from the outside, and/or improve the color purity of light emitted from the display apparatus. In one or more embodiments, the optical function layer may include a retarder and/or a polarizer. The retarder may be of a film type or kind or a liquid crystal coating type or kind, and may include a N/2 retarder and/or a N4 retarder. The polarizer may also be of a film type or kind or a liquid crystal coating type or kind. The film type or kind may include a stretchable synthetic resin film, and the liquid crystal coating type or kind may include liquid crystals in a certain orientation. The retarder and the polarizer may further include a protective film.

An adhesive member may be arranged between the touch electrode layer and the optical function layer. The adhesive member may employ any suitable general member in the corresponding technical field without limitation. The adhesive member may include a pressure sensitive adhesive (PSA).

According to one or more embodiments, temperature may be controlled or selected by (easily) absorbing the heat between the deposition source and the mask assembly. Accordingly, the deposition source and the mask assembly may be arranged closer to each other so that the distance between the deposition source and the mask assembly is decreased, and thus, deposition quality and deposition efficiency may be improved.

The effects of the disclosure are not limited to the above-described effects, and one or more suitable effects that are not described in the specification may be clearly understood from the following descriptions by one skilled in the art to which the present disclosure belongs.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

As used herein, the singular forms “a,” “an” and “the” are intended to include the plural forms as well, unless the context clearly indicates otherwise.

As used herein, the term “substantially,” “about,” and similar terms are used as terms of approximation and not as terms of degree, and are intended to account for the inherent deviations in measured or calculated values that would be recognized by those of ordinary skill in the art. “Substantially” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially” may mean within one or more standard deviations, or within +30%, 20%, 10%, 5% of the stated value.

Also, any numerical range recited herein is intended to include all subranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

Further, the use of “may” when describing embodiments of the present disclosure refers to “one or more embodiments of the present disclosure.”

The light emitting device, electronic apparatus or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

It should be understood that embodiments described herein should be considered in a descriptive sense only and not for purposes of limitation. Descriptions of features or aspects within each embodiment should typically be considered as available for other similar features or aspects in other embodiments. Although the embodiments of the present disclosure have been described, it is understood that the present disclosure should not be limited to these embodiments, but one or more suitable changes and modifications can be made by one ordinary skilled in the art within the spirit and scope of the present disclosure as defined by the following claims and equivalents thereof.

What is claimed is:

1. A deposition source comprising:
a housing accommodating a deposition material therein;
a nozzle connected to the housing, the nozzle being to spray the deposition material accommodated in the housing;
a heating portion adjacent to the housing, the heating portion being to heat the deposition material accommodated in the housing; and
a Peltier plate covering a surface of the housing in which the nozzle is arranged.

2. The deposition source of claim 1, wherein the Peltier plate is to absorb heat outside the deposition source and to transfer the heat to an inside of the deposition source.

3. The deposition source of claim 1, further comprising a deposition frame having an inner space in which the housing and the heating portion are accommodated, the deposition frame having an opening at at least a part of one surface of the deposition frame in which the nozzle is arranged,
wherein the Peltier plate covers the part of the one surface of the deposition frame, and the nozzle extends through the Peltier plate.

4. The deposition source of claim 3, wherein the Peltier plate is a single integral piece that covers an entire open surface of the deposition frame.

5. The deposition source of claim 3, wherein the nozzle comprises a plurality of nozzles, and the Peltier plate comprises a plurality of Peltier plates and a number of the plurality of Peltier plates corresponds to a number of the plurality of nozzles.

6. The deposition source of claim 5, wherein, in a plan view, each of the plurality of Peltier plates is around a respective one of the plurality of nozzles.

7. The deposition source of claim 1, wherein the Peltier plate comprises a first Peltier plate covering an upper surface of the housing in which the nozzle is arranged and a second Peltier plate around side surfaces of the housing.

8. The deposition source of claim 1, further comprising a cooling portion on one surface of the Peltier plate facing the housing to cool heat from the Peltier plate.

9. The deposition source of claim 1, further comprising a reflector between the housing and the Peltier plate, the reflector to reflect and/or reduce heat generated from an inner space of the deposition source from being transferred to an outside of the deposition source.

10. The deposition source of claim 9, wherein the reflector comprises a plurality of reflectors spaced from each other in a direction from the housing to the Peltier plate.

11. The deposition source of claim 1, wherein the Peltier plate comprises a first plate and a second plate, the first plate and the second plate each comprising an insulator, and a Peltier element layer between the first plate and the second plate and comprising a semiconductor.

12. An apparatus for manufacturing a display apparatus, the apparatus comprising:
a mask assembly; and
a deposition source to supply a deposition material toward the mask assembly,
wherein the deposition source comprises:
a housing accommodating a deposition material therein;
a nozzle connected to the housing, the nozzle being to spray the deposition material accommodated in the housing;
a heating portion adjacent to the housing, the heating portion being to heat the deposition material accommodated in the housing; and
a Peltier plate between the housing and the mask assembly.

13. The apparatus of claim 12, wherein the Peltier plate is to absorb heat outside the deposition source and to transfer the heat to an inside of the deposition source.

14. The apparatus of claim 12, further comprising a deposition frame having an inner space in which the housing and the heating portion are accommodated, the deposition frame having an opening at at least a part of one surface of the deposition frame in which the nozzle is arranged,
wherein the Peltier plate covers the part of the one surface of the deposition frame, and the nozzle extends through the Peltier plate.

15. The apparatus of claim 14, wherein the Peltier plate is a single integral piece that covers an entire open surface of the deposition frame.

16. The apparatus of claim 14, wherein the nozzle comprises a plurality of nozzles, and the Peltier plate comprises a plurality of Peltier plates and a number of the plurality of Peltier plates corresponds to a number of the plurality of nozzles.

17. The apparatus of claim 16, wherein, in a plan view, each of the plurality of Peltier plates is around a respective one of the plurality of nozzles.

18. The apparatus of claim 12, wherein the Peltier plate comprises a first Peltier plate covering an upper surface of the housing in which the nozzle is arranged and a second Peltier plate around side surfaces of the housing.

19. The apparatus of claim 12, further comprising a cooling portion on one surface of the Peltier plate facing the housing to cool heat from the Peltier plate.

20. The apparatus of claim 12, further comprising a reflector between the housing and the Peltier plate to reflect and/or reduce heat generated from an inner space of the deposition source from being transferred to an outside of the deposition source.
